(19) United States
(12) Patent Application Publication
(10) Pub. No.: US 2024/0170304 A1
(43) Pub. Date: May 23, 2024

(54) APPARATUS AND METHOD FOR TREATING SUBSTRATE

(71) Applicant: SEMES CO., LTD., Cheonan-si (KR)

(72) Inventors: Ho Jong HWANG, Hwaseong-si (KR); Hyun Goo PARK, Seongnam-si (KR); Hyo Won YANG, Seoul (KR); Ki-Moon KANG, Yongin-si (KR); Sang Min LEE, Seoul (KR); Se Hoon OH, Cheonan-si (KR); Won Sik SON, Hwaseong-si (KR)

(73) Assignee: SEMES CO., LTD., Cheonan-si (KR)

(21) Appl. No.: 18/515,611

(22) Filed: Nov. 21, 2023

(30) Foreign Application Priority Data
Nov. 23, 2022 (KR) 10-2022-0158718

(51) Int. Cl. H01L 21/67

(52) U.S. Cl. CPC H01L 21/67017; H01L 21/67109

(57) ABSTRACT

The inventive concept provides a substrate treating apparatus. The substrate treating apparatus includes treating modules having an opening for taking in and taking out a substrate and which are stacked on each other; and an air flow generating member for generating a downward airflow at each treating module, and wherein the air flow generating member includes: a pan unit configured to supply an air; a spray unit configured to be provided above the treating module and which sprays an air supplied from the pan unit; and an exhaust unit configured to exhaust an air sprayed by the spray unit to outside of the treating module.

### CROSS-REFERENCE TO RELATED APPLICATIONS

A claim for priority under 35 U.S.C. § 119 is made to Korean Patent Application No. 10-2022-0158718 filed on Nov. 23, 2022, in the Korean Intellectual Property Office, the entire contents of which are hereby incorporated by reference.

### BACKGROUND

Embodiments of the inventive concept described herein relate to a substrate treating apparatus and a substrate treating method.

In order to manufacture a semiconductor element, a desired pattern is formed on a substrate through various processes such as a photolithography process, an etching process, an ashing process, an ion injection process, and a thin film deposition process on a substrate such as a wafer. Various treating liquids and treating gases are used in each process. In addition, a drying process is performed on the substrate to remove a treating liquid which is used to treat the substrate from the substrate.

In general, the drying process for removing the treating liquid from the substrate includes a rotary drying process for rotating the substrate at a high speed and removing a treating liquid remaining on the substrate with a centrifugal force by a rotation of the substrate, or a supercritical drying process for removing the treating liquid remaining on the substrate using a supercritical fluid.

The supercritical drying process takes the substrate into a high-pressure chamber capable of maintaining a high-pressure and high-temperature atmosphere, and then supplies the supercritical fluid on the substrate to remove the treating liquid remaining on the substrate (e.g., an organic solvent, a developing liquid solvent, etc.).

In such a supercritical drying process, a temperature uniformity of the substrate is very important. However, a conventional supercritical drying apparatus has a temperature imbalance caused by a stagnant airflow around the high-pressure chamber, a discharge of a fume remaining after a process, and a convective heat transfer.

### SUMMARY

Embodiments of the inventive concept provide a substrate treating apparatus and a substrate treating method for improving a temperature uniformness of a process chamber.

Embodiments of the inventive concept provide a substrate treating apparatus and a substrate treating method which can quickly remove a fume remaining after a process.

Embodiments of the inventive concept provide a substrate treating apparatus and substrate treating method for preventing early drying of a substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes treating modules having an opening for taking in and taking out a substrate and which are stacked on each other; and an air flow generating member for generating a downward airflow at each treating module, and wherein the air flow generating member includes: a pan unit configured to supply an air; a spray unit configured to be provided at above the treating module and which sprays an air supplied from the pan unit; and an exhaust unit configured to exhaust an air sprayed by the spray unit to outside of the treating module.

In an embodiment, the substrate treating apparatus further includes a control unit configured to control the air flow generating member, and wherein the control unit controls a spray amount of the air sprayed by the spray unit and an exhaust amount exhausted through the exhaust unit.

In an embodiment, the treating module includes: a housing having an inner space and the opening; and an inner chamber which is provided at the inner space and having a treating space for treating the substrate, and the substrate treating apparatus further including: a control unit configured to control the spray unit and the exhaust unit so a downward airflow at the inner space is provided at a different speed according to substrate treating steps at the treating module.

In an embodiment, the substrate treating step includes: taking in the substrate to the treating space; process treating the substrate at the treating space; and taking out the substrate from the treating space, and wherein the control unit controls the spray unit so an air amount supplied to the inner space at the taking in the substrate is relatively smaller than an air amount supplied to the inner space at the process treating the substrate and the taking out the substrate.

In an embodiment, the control unit controls the spray unit and the exhaust unit so a supply amount and an exhaust amount of an air supplied to the inner space at the taking out the substrate is relatively larger than a supply amount and an exhaust amount of an air supplied to the inner space at the process treating the substrate and the taking out the substrate.

In an embodiment, the spray unit includes: a diffuser connected to a supply duct which is connected to the pan unit; and an intake side damper for adjusting a supply amount of the air, and wherein the intake side damper is controlled by the control unit.

In an embodiment, the exhaust unit includes: an inner exhaust duct provided at a bottom of the housing, which has an inlet to intake the air and which is connected to an outer exhaust duct; and an exhaust side damper for adjusting an exhaust amount of the air, and wherein the exhaust side damper is controlled by the control unit.

In an embodiment, the inner chamber is a high pressure chamber for performing a supercritical treating process with respect to the substrate, and a supercritical fluid is supplied to the treating space through a fluid supply line connected to a high pressure chamber in a state in which the treating space is sealed.

The inventive concept provides a substrate treating method. The substrate treating method includes process treating a substrate at a process chamber positioned at an inner space of a housing having a substrate inlet, and a taking in the substrate to the process chamber is an air flow provided at the inner space is downflowed to a first speed, and a taking out the substrate from the process chamber is the air flow provided at the inner space is downflowed to a second speed which is different from the first speed.

In an embodiment, the second speed is higher than the first speed.

In an embodiment, the process chamber treats the substrate at a high-pressure state.

In an embodiment, the substrate taken into the process chamber is wet with a liquid film remaining.

In an embodiment, the substrate is dried at the process chamber using a supercritical fluid.

In an embodiment, the process chamber is opened/closed by a relative up/down movement of a top housing and a bottom housing which couple to each other to provide a treating space.

In an embodiment, an air flow in the inner space is downflowed to the second speed before the process chamber is opened.

In an embodiment, the air flow provided at the inner space is provided by an air supplied from a pan unit being sprayed by a diffuser provided at a top of the inner space, and an air sprayed to the inner space being exhausted to an outside through an inner exhaust duct which is provided at a bottom of the inner space.

In an embodiment, an air supply amount supplied to the inner space at the taking in the substrate is relatively smaller than an air supply amount supplied to the inner space at the process treating the substrate at the process chamber and the taking out the substrate.

In an embodiment, an air supply amount supplied to the inner space and an air exhaust amount exhausted from the inner space during the taking out the substrate is relatively larger than an air supply amount supplied to the inner space and an air exhaust amount exhausted from the inner space during the taking in the substrate.

The inventive concept provides a substrate treating method. The substrate treating method includes a treating a substrate at a high pressure chamber positioned at an inner space of a housing having a substrate inlet, and an air flow provided at the inner space is downflowed to a first speed during a taking in the substrate to the high pressure chamber, and an air flow provided at the inner space is downflowed to a second speed during a taking out the substrate at which the substrate is taken out from the process chamber, wherein the second speed is faster than the first speed, and the substrate which is taken into the process chamber is wet with a liquid film remaining.

In an embodiment, the substrate is dried at the process chamber using the supercritical fluid, the air flow is downflowed to the second speed at the inner space before the process chamber is opened, an air supply amount supplied to the inner space during the taking in the substrate is relatively smaller than an air supply amount supplied to the inner space at the taking out the substrate, and an air supply amount supplied to the inner space and an air exhaust amount exhausted from the inner space during the taking out the substrate is relatively larger than an air supply amount supplied to the inner space and an air exhaust amount exhausted from the inner space during the taking in the substrate.

According to an embodiment of the inventive concept, a temperature imbalance of an inner chamber can be minimized by forming a downward airflow at an inner space.

According to an embodiment of the inventive concept, a fume remaining after a process can be quickly removed.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a plan view schematically illustrating a substrate treating apparatus according to an embodiment of the inventive concept.

FIG. 2 is a side cross-sectional view of the substrate treating apparatus illustrated in FIG. 1.

FIG. 3 is a cross-sectional view schematically illustrating an embodiment of a liquid treating module of FIG. 1.

FIG. 4 illustrates a tower formed by stacking a drying module shown in FIG. 2.

FIG. 5 illustrates an exhaust unit formed in a bottom of the drying module.

FIG. 6 schematically illustrates illustrating an embodiment of the drying module of FIG. 4.

FIG. 7 is a configuration view for illustrating a controller controlling a spray unit and an exhaust unit.

FIG. 8 is a flowchart illustrating a substrate treating method according to an embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

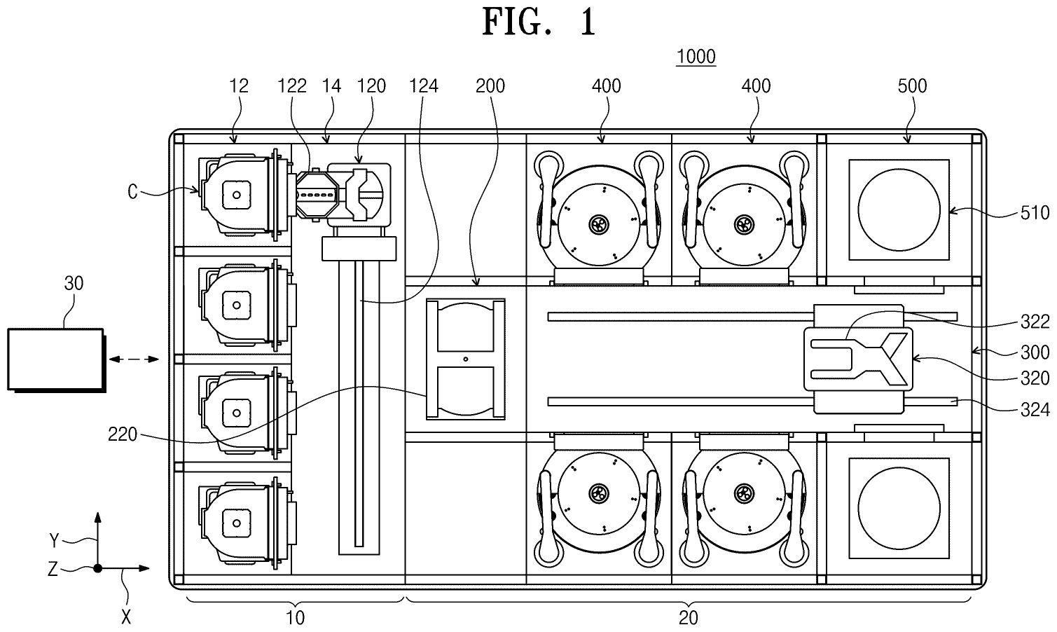

Hereinafter, example embodiments of the inventive concept will be described with reference to FIG. 1 to FIG. 8.

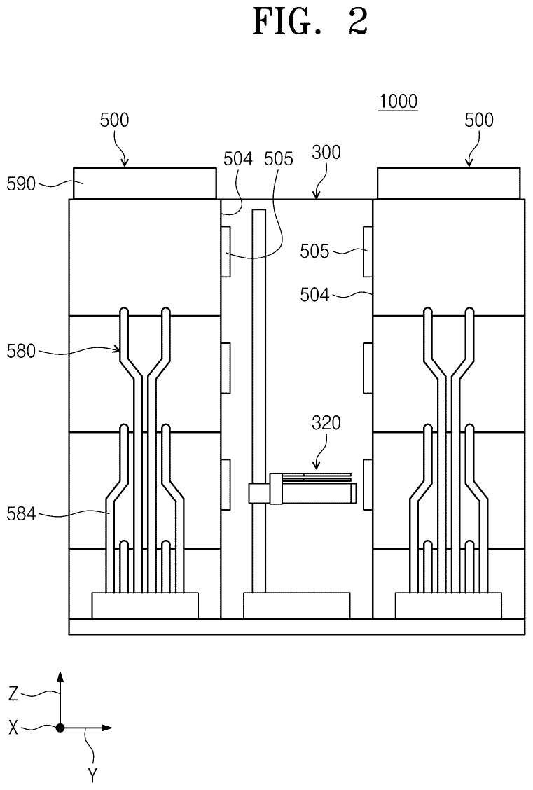

FIG. 1 is a plan view schematically illustrating a substrate treating apparatus according to an embodiment of the inventive concept, and FIG. 2 is a side cross-sectional view of the substrate treating apparatus illustrated in FIG. 1.

Referring to FIG. 1 and FIG. 2, the substrate treating apparatus 1000 includes an index module 10, a treating module 20, and a controller 30.

The index module 10 and the treating module 20 are disposed in a direction when seen from above. Hereinafter, the direction in which the index module 10 and the treating module 20 are disposed will be referred to as a first direction X, a direction perpendicular to the first direction X will be referred to as a second direction Y, and a direction perpendicular to both the first direction X and the second direction Y will be referred to as a third direction Z.

The index module 10 transfers a substrate W (for example, a wafer) from a container C in which the substrate W is stored to the treating module 20, and stores a substrate W to which a treating has been completed at the treating module 20 in the container C. A lengthwise direction of the index module 10 is provided in the second direction Y. The index module 10 has a load port 12 and an index frame 14. The index frame 14 is positioned between the load port 12 and the treating module 20. The container C in which the substrates are stored is placed on the load port 12. A plurality of load ports 12 may be provided, and the plurality of load ports 12 may be disposed along the second direction Y.

For the container C, a sealed container such as a front open unified pod FOUP may be used. The container C may be placed on the load port 12 by a transfer means (not illustrated) such as an overhead transfer, an overhead conveyor, or an automatic guided vehicle or by an operator.

The index frame 14 is provided with an index robot 120. In the index frame 14, a guide rail 124 with its lengthwise direction in the second direction Y may be provided, and the index robot 120 may be provided to be movable along the guide rail 124. The index robot 120 may include a hand 122 on which the substrate W is placed, and the hand 122 may be forwardly and backwardly movable, rotatable around the third direction Z, and movable along the third direction Z. A plurality of hands 122 are provided to be spaced apart in an up/down direction, and the hands 122 may be forwardly and backwardly movable independently of each other.

The controller 30 may control the substrate treating apparatus. The controller may include a process controller e.g., a microprocessor (computer) that executes a control of the substrate treating apparatus, a user interface e.g., a keyboard in which an operator performs a command input operation or the like in order to manage the substrate treating apparatus, a display for visualizing and displaying an operation situation of the substrate treating apparatus, and the like, and a storage unit storing a control program for executing the process performed in the substrate treating apparatus under the control of the process controller, a various data and a program (i.e., treatment recipe) for executing various process in each component according to treating conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.—

The controller 30 may control the substrate treating apparatus to perform a substrate treating method illustrated below. For example, the controller 30 may control the air flow generating member, a fluid supply unit 530, and a fluid exhaust unit 550 to perform the substrate treating method illustrated below.

The treating module 20 includes a buffer unit 200, a transfer chamber 300, a liquid treating module 400, a drying module 500, and a post-treating chamber 600. The buffer unit 200 provides a space in which the substrate W carried into the treating module 20 and the substrate W carried out from the treating module 20 temporarily stay. The liquid treating module 400 supplies a liquid onto the substrate W to perform a liquid treatment process of liquid treating the substrate W. The drying module 500 performs a drying process of removing a liquid remaining on the substrate W. The transfer chamber 300 transfers the substrate W between the buffer unit 200, the liquid treating module 400, and drying module 500, and the post-treating chamber 600.

A lengthwise direction of the transfer chamber 300 may be provided in the first direction X. The buffer unit 200 may be disposed between the index module 10 and the transfer chamber 300. The liquid treating module 400 and the drying module 500 may be disposed on a side of the transfer chamber 300. The liquid treating module 400 and the transfer chamber 300 may be disposed along the second direction Y. The drying module 500 and the transfer chamber 300 may be disposed along the second direction Y. The buffer unit 200 may be positioned at an end of the transfer chamber 300.

According to an embodiment, the liquid treating modules 400 may be disposed on both sides of the transfer chamber 300, the drying modules 500 may be disposed on both sides of the transfer chamber 300, and the liquid treating modules 400 may be disposed closer to the buffer unit 200 than the drying modules 500. However, the embodiment is not limited to this.

At one and/or both sides of the transfer chamber 300, the liquid treating modules 400 may be provided in an array of A×B (A and B are natural numbers greater than 1 or 1) along the first direction X and the third direction Z. Also, at a side/or both sides of the transfer chamber 300, the drying modules 500 may be provided in an array of C×D (C and D are natural numbers greater than 1 or 1) along the first direction X and the third direction Z. The drying module 500 may be stacked in a vertical direction to form a tower.

The transfer chamber 300 has a transfer robot 320. In the transfer chamber 300, a guide rail 324 with its lengthwise direction provided in the first direction X may be provided, and the transfer robot 320 may be provided to be movable on the guide rail 324. The transfer robot 320 may include a hand 322 on which the substrate W is placed, and the hand 322 may be provided to be forwardly and backwardly movable, rotatable around the third direction Z as an axis, and movable along the third direction Z. A plurality of hands 322 are provided to be spaced apart in the up/down direction, and the hands 322 may be forwardly and backwardly movable independently from each other.

The buffer unit 200 includes a plurality of buffers 220 on which the substrate W is placed. The buffers 220 may be disposed to be spaced apart from each other in the third direction Z. A front face and a rear face of the buffer unit 200 are opened. The front face is a surface facing the index module 10, and the rear face is a surface facing the transfer chamber 300. The index robot 120 may access the buffer unit 200 through the front face, and the transfer robot 320 may access the buffer unit 200 through the rear face.

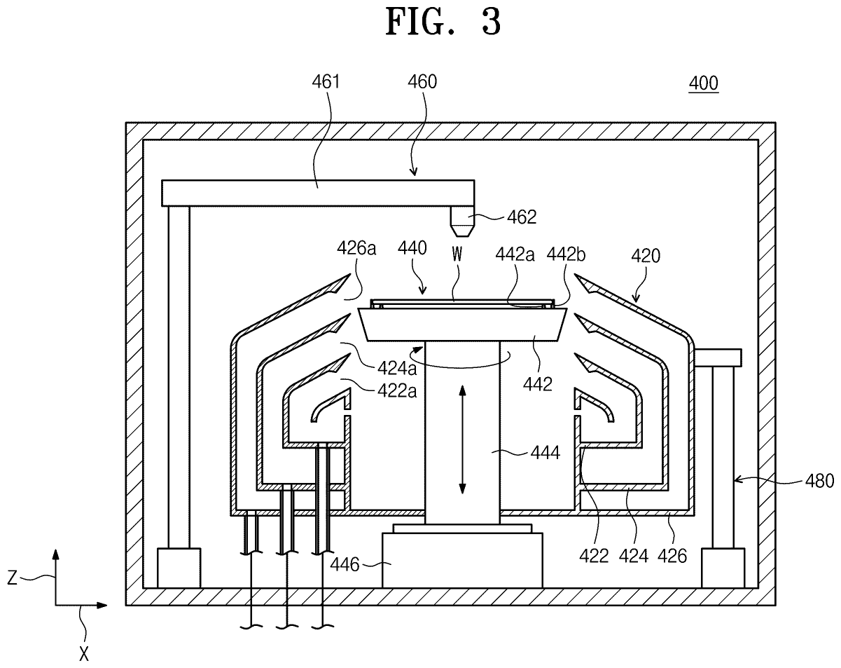

FIG. 3 is a cross-sectional view schematically illustrating an embodiment of a liquid treating chamber of FIG. 1.

Referring to FIG. 3, the liquid treating module 400 includes a housing 410, a cup 420, a support unit 440, a liquid supply unit 460, and a lifting/lowering unit 480.

The housing 410 may have an inner space in which the substrate W is treated. The housing 410 may have a generally hexahedral shape. For example, the housing 410 may have a rectangular parallelepiped shape. In addition, an opening (not shown) through which the substrate W is taken in or taken out may be formed in the housing 410. In addition, a door (not shown) for selectively opening and closing the opening may be installed in the housing 410.

The cup 420 may have a container shape with an open top. The cup 420 may have a treating space, and the substrate W may be liquid-treated in the treating space. The support unit 440 supports the substrate W in the treating space. The liquid supply unit 460 supplies the treating liquid onto the substrate W supported by the support unit 440. The treating liquid may be provided in a plurality of types and may be sequentially supplied onto the substrate W. The lifting/lowering unit 480 adjusts a relative height between the cup 420 and the support unit 440.

In an embodiment, the cup 420 has a plurality of recollecting containers 422, 424, and 426. Each of the recollecting containers 422, 424, and 426 has a recollecting space for recollecting the liquid used for substrate treatment. Each of the recollecting containers 422, 424, and 426 is provided in a ring shape surrounding the support unit 440. During a liquid treatment process, the treating liquid scattered by a rotation of the substrate W is introduced into the recollecting space through the inlets 422a, 424a, and 426a of each respective recollecting container 422, 424, and 426. According to an embodiment, the cup 420 has a first recollecting container 422, a second recollecting container 424, and a third recollecting container 426. The first recollecting container 422 is disposed to surround the support unit 440, the second recollecting container 424 is disposed to surround the first recollecting container 422, and the third recollecting container 426 is disposed to surround the second recollecting container 424. The second inlet 424a introducing the liquid into the second recollecting container 424 may be positioned above the first inlet 422a introducing the liquid into the first recollecting container 422, and the third inlet 426a introducing the liquid into the third recollecting container 424a may be positioned above the second inlet 424a.

The support unit 440 has a support plate 442 and a drive shaft 444. A top surface of the support plate 442 is provided in a substantially circular shape and may have a diameter larger than that of the substrate W. A support pin 442a is provided at a central part of the support plate 442 to support a bottom surface of the substrate W, and the support pin 442a is provided to protrude from the support plate 442 such that the substrate W is spaced apart from the support plate 442 by a predetermined distance. A chuck pin 442b is provided at an edge of the support plate 442. The chuck pin 442b is provided to upwardly protrude from the support plate 442, and supports a side of the substrate W so that the substrate W is stably held by the support unit 440 when the substrate W is rotated. The drive shaft 444 is driven by the driver 446, is connected to the center of the bottom surface of the substrate W, and rotates the support plate 442 based on its central axis.

According to an embodiment, the liquid supply unit 460 may include a nozzle 462. The nozzle 462 may supply the treating liquid to the substrate W. The treating liquid may be a chemical, a rinsing liquid, or an organic solvent. The chemical may be a chemical with strong acid properties or strong base properties. In addition, the rinsing liquid may be a deionized water. In addition, the organic solvent may be an isopropyl alcohol (IPA). Also, a treating liquid supplied by the liquid supply unit 460 may be a developing liquid. For example, the developing liquid supplied by the liquid supply unit 460 may include an N-Butyl Acetate.

Also, the liquid supply unit 460 may include a plurality of nozzles 462, and each nozzle 462 may supply a different type of treating liquid. For example, one of the nozzles 462 may supply a chemical, another one of the nozzles 462 may supply the rinsing liquid, and still another one of the nozzles 462 may supply an organic solvent. In addition, the controller 30 may control the liquid supply unit 460 to supply the organic solvent from the still another one of the nozzles 462 to the substrate W after supplying the rinsing liquid to the substrate W from the another one of the nozzles 462. Accordingly, the rinsing liquid supplied onto the substrate W may be substituted with an organic solvent having a small surface tension. Also, any one among the nozzles 462 may supply the developing liquid.

The lifting/lowering unit 480 moves the cup 420 in the up/down direction. A relative height between the cup 420 and the substrate W is changed by the up/down vertical movement of the cup 420. As a result, the recollecting containers 422, 424, 426 for recollecting the treating liquid are changed in accordance with a type of liquid supplied to the substrate W, so that the liquids can be recollected separately. Unlike the above description, the cup 420 is fixedly installed, and the lifting/lowering unit 480 may move the support unit 440 in the up/down direction.

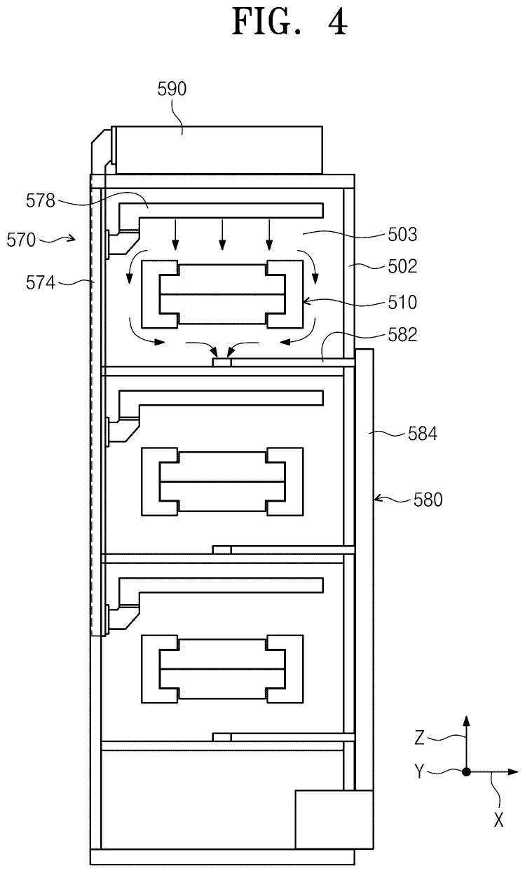

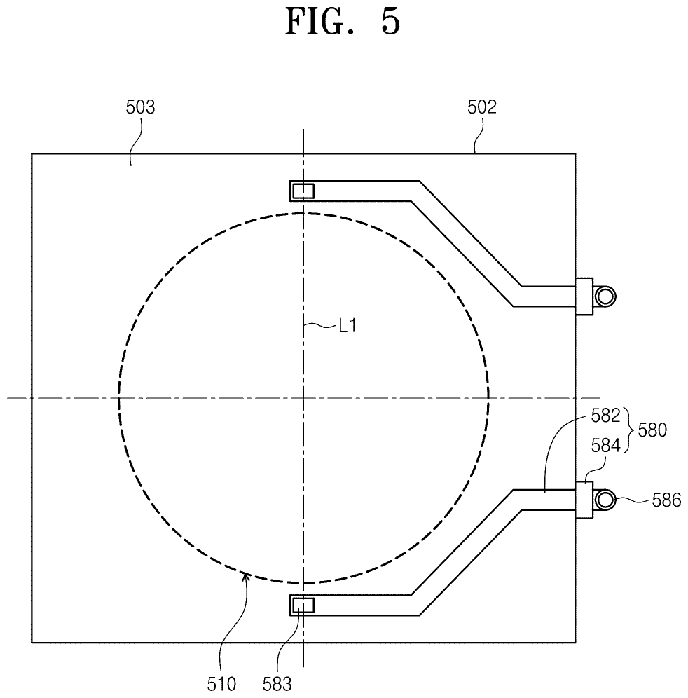

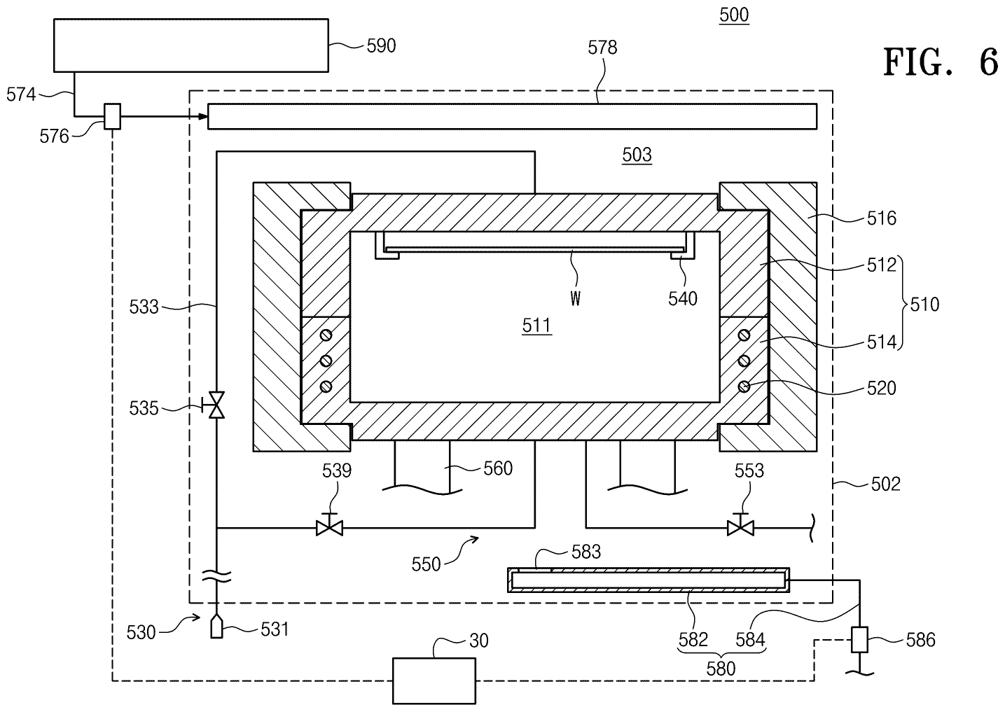

FIG. 4 illustrates a tower formed by stacking a drying module shown in FIG. 2, FIG. 5 illustrates an exhaust unit formed in a bottom of the drying module, and FIG. 6 schematically illustrates an embodiment of the drying module of FIG. 4

Referring to FIG. 4 to FIG. 6, the drying module 500 according to an embodiment of the inventive concept can remove a treating liquid remaining on the substrate W using a treating fluid SC in a supercritical state. A treating liquid to be removed may be any one of an above-described chemical, rinsing liquid, organic solvent, and developing liquid. In addition, the treating fluid SC may include a carbon dioxide (CO₂). For example, the drying module 500 can remove the developing liquid, which is an N-butyl acetic acid remaining on the substrate W, from the substrate W using the carbon dioxide (CO₂) in a supercritical state.

The drying module 500 may include a housing 502, an inner chamber 510, a heating member 520, a fluid supply unit 530, a support member 540, a fluid discharge unit 550, a lifting/lowering member 560, and an airflow supply member.

An airflow generating member provides a downward airflow to the housing 502 of the drying module 500. According to an embodiment, the airflow generating member may include a fan unit 590, a spray unit 570, and an exhaust unit 580.

The fan unit 590 may be provided at a top end of a tower in which the drying modules 500 are stacked.

The spray unit 570 receives an air from the fan unit 590 and supplies the air to the housing 502. The spray unit 570 may include a diffuser 578 connected to a supply duct 574 connected to the fan unit 590 and an intake side damper 576 for adjusting a supply amount of the air. The diffuser 578 is positioned above the inner chamber 510.

The exhaust unit 580 exhausts the air sprayed from the spray unit 570 to the outside of the treating module 500. The exhaust unit 580 may include an inner exhaust duct 582 and an outer exhaust duct 584. The inner exhaust duct 582 has an inlet 583 provided at a bottom region of the housing 502 for intaking the air. For a uniform exhaust, the suction port 583 is positioned at any center line L1 passing through a center of the housing. The suction port 583 is positioned away from the inner chamber 510 when viewed from above. An exhaust-side damper 586 may be provided at a portion to which the inner exhaust duct 582 and the outer exhaust duct 584 are connected.

The housing 502 provides an inner space. An opening 505 for taking in and taking out the substrate is provided on a front surface 504 of the housing 502. The front surface 504 of the housing 502 is provided to contact the transfer chamber. The opening may be opened and closed by a shutter cover (not shown).

The inner chamber 510 may be a high pressure chamber which provides a space in which a supercritical drying process is performed. The inner chamber 510 may provide a treating space 511 in which the substrate W is dried by the treating fluid SC in a supercritical state. The inner chamber 510 is provided with a material capable of enduring a high pressure greater than or equal to a threshold pressure.

In an embodiment, the inner chamber 510 may include a top body 512 and a bottom body 514. The top body 512 and the bottom body 514 may couple with each other to form the treating space 511. Any one of the top body 512 and the bottom body 514 may be coupled to the lifting/lowering member 560 to be moved in the vertical direction. For example, the bottom body 514 may be coupled to the lifting/lowering member 560 and may be moved in a vertical direction by the lifting/lowering member 560. Accordingly, the treating space 511 of the body 510 may be selectively sealed. The top body 512 and the bottom body 514 may be clamped by a clamp member 516. In the aforementioned example, the bottom body 514 is combined with the lifting/lowering member 560 to move in the vertical direction, but the inventive concept is not limited to it. For example, the top body 512 may be coupled to the lifting/lowering member 560 to move in the vertical direction.

If the bottom body 514 is spaced apart from the top body 512, the treating space 511 is opened, and at this time, the substrate W is taken in or taken out. During the process, the bottom body 514 is in close contact with the top body 512 to seal the treating space 511 from the outside. Here, the substrate W may be taken in from the liquid treating module while going through an organic solvent process in a state in which an organic solvent remains.

The heating member 520 may heat the treating fluid SC supplied to the treating space 511. The heating member 520 may increase a temperature of the treating space 511 of the body 510. As the heating member 520 increases the temperature of the treating space 511, the treating fluid SC supplied to the treating space 511 can be converted to a supercritical state or maintained in a supercritical state.

In addition, the heating member 520 may be buried in the body 510. For example, the heating member 520 may be buried in any one of the top body 512 and the bottom body 514. For example, the heating member 520 may be provided in the bottom body 514. However, it is not limited to this, and the heating member 520 can be provided at various locations to increase the temperature of the treating space 511. In addition, the heating member 520 may be a heater. However, it is not limited to this, and the heating member 520 can be modified into a known device that can increase the temperature of the treating space 511.

The fluid supply unit 530 may supply the treating fluid SC to the treating space 511 of the body 510. The treating fluid SC supplied by the fluid supply unit 530 may include a carbon dioxide (CO₂). The fluid supply unit 530 may include a fluid supply source 531, a first supply line 533, a first supply valve 535, a second supply line 537, and a second supply valve 539.

The fluid supply source 531 may store the treating fluid SC supplied to the treating space 511 of the body 510 or may supply the treating fluid SC to the treating space 511. The fluid supply source 531 may supply the treating fluid SC to the treating space 511 via a first supply line 533 and/or a second supply line 537. Also, a first supply valve 535 may be installed at the first supply line 533. Also, a second supply valve 539 may be installed at the second supply line 537. The first supply valve 535 and the second supply valve 539 may be an open/close valve such as an on/off valve. Selectively, the first supply valve 535 and the second supply valve 539 may be a flow rate control valve. According to an open/close of the first supply valve 535 and the second supply valve 539, the treating fluid SC may be selectively flow at the first supply line 533 or the second supply line 537.

An end of the first supply line 533 may communicate with the treating space 511. The first supply line 533 may be a top supply line supplying the treating fluid SC which is a drying gas from a top of the treating space 511 of the body 510. At least a portion of the first supply line 53 may be provided at the top body 512. Also, the first supply line 533 may be configured so a supply of the treating fluid SC faces the top surface of the substrate W supported on the support member 540. For example, the treating fluid SC supplied from the first supply line 533 may be supplied to the top surface of the substrate W. The treating fluid SC supplied from the first supply line 533 may flow in a top to a bottom direction. For example. the treating fluid SC supplied from the first supply line 533 may flow from a top region of the substrate W supported at the treating space to a bottom region of the substrate W.

An end of the second supply line 537 may communicate with the treating space 511. The second supply line 537 may be a bottom supply line supplying the treating fluid SC which is a drying gas to a bottom of the treating space 511 of the body 510. At least a portion of the second supply line 537 may be provided at the bottom body 514. Also, the second supply line 537 may be configured so a supply of the treating fluid SC faces a bottom region of the substrate W supported on the support member 540. For example, the treating fluid SC supplied from the second supply line 537 may be supplied from a bottom to a top direction. For example, the treating fluid SC supplied from the second supply line 537 may flow from a bottom region of the substrate W supported in the treating space 511 toward a top region of the substrate W.

In the above example, it was described as an example that the first supply line 533 and the second supply line 537 are connected to one fluid supply source 531, but the inventive concept is not limited to this. For example, a plurality of fluid sources 531 may be provided, the first supply line 533 may be connected to any one of the plurality of fluid sources 531, and the second supply line 537 may be connected to the another of the fluid sources 531.

In addition, various elements such as a pressure sensor, a temperature sensor, a flow control valve, an orifice, and a heater may be installed and placed in the abovementioned first supply line 533, second supply line 537, or a line between a point connecting the first supply line 533 and the second supply line 537 and the fluid supply source 531.

The support member 540 may support the substrate W in the treating space 511. The support member 540 may be configured to support an edge region of the substrate W in the treating space 511. For example, the support member 540 may be configured to support a bottom surface of the edge region of the substrate W in the treating space 511.

The fluid discharge unit 550 may discharge the treating fluid SC to the outside from the treating space 511 of the body 510. The fluid discharge unit 550 may include a fluid discharge line 551 and a discharge valve 553. An end of the fluid discharge line 551 may communicate with the treating space 511. At least a portion of the fluid discharge line 551 may be provided at the bottom body 514. When the treating fluid SC is discharged from the treating space 511, the fluid discharge line 551 may be configured so that the treating fluid SC flows from a top to a bottom of the treating space 511.

In addition, a discharge valve 553 may be installed in the fluid discharge line 551. The discharge valve 553 may be an on/off valve, for example, an opening/closing valve. The discharge valve 553 may be a flow rate control valve. In the fluid discharge line 551, an element such as an orifice, a pressure sensor, a temperature sensor, and a pump may be variously installed and placed.

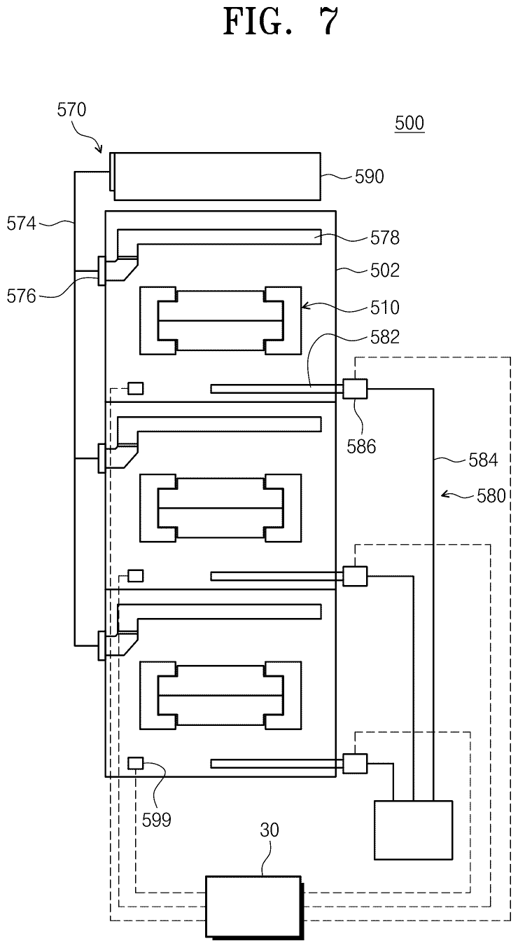

FIG. 7 is a configuration view for illustrating a controller controlling a spray unit and an exhaust unit.

Referring to FIG. 7, a spray amount sprayed through the spray unit 570 and an exhaust amount exhausted through the exhaust unit 580 can be controlled by the control unit 30. To this end, the intake-side damper 576 and the exhaust-side damper 586 may be controlled by the controller 30. The controller 30 may control an inner airflow by a differential pressure control method. That is, the control unit 30 may control the intake side damper 576 and the exhaust side damper 586 with a measured value of a differential pressure sensor 599 installed in the inner space.

The controller may control the inner airflow for each process step. That is, the control unit 30 may control the intake side damper 576 and the exhaust side damper 586 so that a downward airflow in the treating space is provided at different speeds (flow rates) for each substrate treating step in the drying module 500. In an embodiment, the airflow provided in the inner space 503 may downflow at a first speed during the taking-in step of the substrate into the inner chamber 510 and the airflow provided in the inner space 503 may downflow at a second speed faster than the first speed during the taking-out step of the substrate from the inner chamber 510. That is, the control unit 30 can control the intake side damper 576 so that an air amount supplied to the inner space 503 at a substrate-taking in step at which the substrate is taken in to the treating space 511, is relatively less than an air amount supplied to the inner space at a process treating step and a substrate taking-out step. In addition, the control unit 30 can control the intake damper 576 and the exhaust damper 586 so that an air supply amount and an air exhaust amount to/from the inner space 503 at the substrate taking-out step is relatively larger than an air supply amount and an air exhaust amount to/from the inner space 503 during the process treating step and substrate taking-in step.

As described above, the drying module of the inventive concept may minimize a temperature imbalance of the inner chamber by forming a downward air current in the inner space.

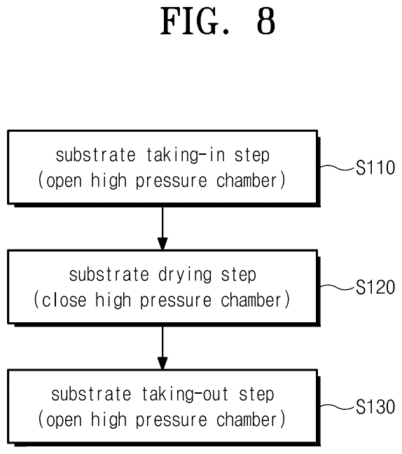

FIG. 8 is a flowchart illustrating a substrate treating method according to an embodiment of the inventive concept.

Referring to FIG. 8, the substrate treating method according to an embodiment of the inventive concept may include a substrate taking-in step S110, a drying step S120, and a substrate taking-out step S130.

In the substrate taking-in step S110, the substrate is taken into the inner chamber 510. The substrate may be a substrate which has completed a liquid treatment in the liquid treating module. The substrate may be transferred to the inner chamber 510 by a transfer robot. A treating liquid may remain on the substrate which is transferred by the transfer robot. For example, an organic solvent may remain on the substrate W. For example, a developing liquid may remain on the substrate W. That is, the substrate W may be transferred to the inner chamber 510 of the drying module with a top surface wet with a developing liquid or an organic solvent. In the substrate taking-in step, the airflow provided in the inner space downflows at the first speed. In order to prevent a wet substrate from being dried in the substrate taking-in step, a flow rate of the air may be relatively small compared to other steps.

The drying step S120 is a step of drying the substrate W using a treating fluid in a supercritical state after the substrate W is taken into the inner space 511. The drying step S120 may be performed in the inner chamber 510. In the drying step S120, the substrate W can be dried by supplying the treating fluid from the inner space 511 of the inner chamber 510 to the substrate W. For example, in the drying step S120, the treating fluid in a supercritical state may be transferred to the substrate W in the treating space 511. The treating fluid in the supercritical state transferred to the substrate W is mixed with the treating liquid remaining on the top surface of the substrate W. Also, as the treating fluid mixed with the treating liquid is discharged from the inner space 511, the treating liquid may be removed from the substrate W.

In the substrate taking-out step S130, the substrate is taken out of the inner chamber 510. The substrate may be transferred by a transfer robot. The inner chamber is opened to remove the substrate. When the inner chamber is opened, a fume remaining in the treating space may diffuse to the inner space. Accordingly, in substrate taking-out step, the supply amount of the air supplied to the inner space 503 and the exhaust amount may be increased to quickly remove the fume.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

1. A substrate treating apparatus comprising:
treating modules having an opening for taking in and taking out a substrate and which are stacked on each other; and
an air flow generating member for generating a downward airflow at each treating module, and
wherein the air flow generating member includes:
a pan unit configured to supply an air;
a spray unit configured to be provided above the treating module and which sprays an air supplied from the pan unit; and
an exhaust unit configured to exhaust an air sprayed by the spray unit to outside of the treating module.

2. The substrate treating apparatus of claim 1 further comprising a control unit configured to control the air flow generating member, and
wherein the control unit controls a spray amount of the air sprayed by the spray unit and an exhaust amount exhausted through the exhaust unit.

3. The substrate treating apparatus of claim 1, wherein the treating module includes:
a housing having an inner space and the opening; and
an inner chamber which is provided at the inner space and having a treating space for treating the substrate, and
the substrate treating apparatus further comprising:
a control unit configured to control the spray unit and the exhaust unit so a downward airflow at the inner space is provided at a different speed depending on each substrate treating step at the treating module.

4. The substrate treating apparatus of claim 3, wherein the substrate treating step includes:
taking in the substrate to the treating space;
process treating the substrate at the treating space; and
taking out the substrate from the treating space, and
wherein the control unit controls the spray unit so an air amount supplied to the inner space during the taking in the substrate is relatively smaller than an air amount supplied to the inner space during the process treating the substrate and the taking out the substrate.

5. The substrate treating apparatus of claim 3, wherein the control unit controls the spray unit and the exhaust unit so a supply amount and an exhaust amount of an air supplied to the inner space during the taking out the substrate is relatively larger than a supply amount and an exhaust amount of an air supplied to the inner space during the process treating the substrate and the taking out the substrate.

6. The substrate treating apparatus of claim 3, wherein the spray unit includes:
a diffuser connected to a supply duct which is connected to the pan unit; and
an intake side damper for adjusting a supply amount of the air, and
wherein the intake side damper is controlled by the control unit.

7. The substrate treating apparatus of claim 3, wherein the exhaust unit includes:
an inner exhaust duct provided at a bottom of the housing, which has an inlet to intake the air and which is connected to an outer exhaust duct; and
an exhaust side damper for adjusting an exhaust amount of the air, and
wherein the exhaust side damper is controlled by the control unit.

8. The substrate treating apparatus of claim 3, wherein the inner chamber is a high pressure chamber for performing a supercritical treating process to the substrate, and
a supercritical fluid is supplied to the treating space through a fluid supply line connected to the high pressure chamber in a state in which the treating space is sealed.

9-20. (canceled)
